(19) United States
(12) Patent Application Publication
(10) Pub. No.: US 2026/0257870 A1
(43) Pub. Date: Sep. 3, 2026

(54) TRAVELING-VEHICLE SYSTEM

(71) Applicant: Murata Machinery, Ltd., Kyoto-shi, Kyoto (JP)

(72) Inventor: Makoto KOBAYASHI, Kyoto-shi (JP)

(21) Appl. No.: 19/163,134

(22) PCT Filed: Feb. 6, 2024
(86) PCT No.: PCT/JP2024/003920

§ 371 Date: Sep. 8, 2025

(30) Foreign Application Priority Data
Mar. 14, 2023 (JP) 2023-039924

(51) Int. Cl. B65G 35/06

(52) U.S. Cl. CPC B65G 35/06

(57) ABSTRACT

A traveling vehicle system includes a working track connected to a traveling track and including an opening at least a portion a traveling unit to an external space, a stopper included in the traveling unit against which a roller rotatable around an axis extending in a vertical direction is to be pressed, the stopper being movable to advance or retreat with respect to a moving region a traveling vehicle on the working track, and a pusher to move the traveling unit in one direction and press the roller against the stopper from the one direction to position the traveling unit at a predetermined position on the working track.

### BACKGROUND OF THE INVENTION

### 1. Field of the Invention

Example embodiments of the present invention relate to traveling vehicle systems.

### 2. Description of the Related Art

There is known an overhead traveling vehicle including a traveling unit that travels along a track, a suspension unit that suspends from the traveling unit, and a lift unit that includes a grip unit that grips an article and elevates and lowers with respect to the suspension unit by winding and unwinding a plurality of suspensions. The traveling unit of such a traveling vehicle travels on a track including a pair of left and right side walls and a base portion connecting upper ends of the pair of side walls. This track is formed in a C-shape in cross-sectional view so as to form a space for accommodating the traveling unit. On each of the pair of side walls, a power feeder that feeds electric power to the traveling vehicle is provided along an extending direction.

In such a traveling vehicle, it is necessary to periodically perform maintenance of the traveling unit. However, since the track of related art is formed such that the traveling unit travels inside an accommodation space, it is necessary to expose the traveling unit in order to perform maintenance. In Japanese U.S. Pat. No. 7,099,622, there are provided a working track on which a traveling vehicle cannot self-propel because an opening is formed in a side wall to expose a traveling unit, and a mover that moves the traveling vehicle in one direction along the working

### SUMMARY OF THE INVENTION

For example, the traveling unit may be stopped at a predetermined position on the working track, and each unit of the traveling unit may be inspected by, for example, a sensor or the like provided at a stop position. However, since the mover of the traveling vehicle system of the related art is configured to sandwich and move the suspension unit suspended from the traveling unit, it is difficult to accurately stop the traveling unit in the traveling vehicle at a predetermined position on the working track. In addition, even in a state where the traveling unit can self-propel, there is a limit to positional accuracy of controlling a driver of the traveling unit to stop the traveling unit at a predetermined position.

Therefore, example embodiments of the present invention provide traveling vehicle systems each capable of improving positional accuracy when a traveling unit in a traveling vehicle is stopped at a predetermined position on a working track.

A traveling vehicle system according to an example embodiment of the present invention includes a traveling vehicle to travel on a traveling track on which a traveling unit of the traveling vehicle travels and including a main body extending along a traveling path of the traveling vehicle, a working track connected to the traveling track and including an opening to expose at least a portion of the traveling unit to an external space, a stopper movable to advance or retreat with respect to a moving region of the traveling unit on the working track, the stopper being included in the traveling unit and against which a roller rotatable around an axis extending in a vertical direction is to be pressed, and a pusher to move the traveling unit in the one direction and press the roller against the stopper from the one direction to position the traveling unit at a predetermined position on the working track.

In the traveling vehicle system having this configuration, the stopper and the pusher to position the traveling unit at the predetermined position on the working track are provided. Specifically, the pusher presses the roller provided in the traveling unit in one direction against the stopper movable to advance or retreat with respect to the moving region of the traveling unit, and thus, the traveling unit is positioned at the predetermined position. As a result, it is possible to improve the positional accuracy when the traveling unit of the traveling vehicle is stopped at the predetermined position on the working track, as compared with, for example, stopping the traveling unit at the predetermined position on the working track by controlling the driver of the traveling unit or controlling the mover that moves the traveling vehicle.

In a traveling vehicle system according to an example embodiment of the present invention, the stopper and the pusher may movable to advance or retreat along a width direction orthogonal to both a moving direction and a vertical direction of the traveling unit with respect to the moving region of the traveling unit on the working track. In this configuration, both the stopper and the pusher are movable to advance or retreat along the width direction. As a result, even in a case where the upper side and the lower side of the roller are covered with various parts, a traveling surface, or the like on the working track, in the stopper, an advance state where the roller is pressed and a retreat state where the traveling unit can pass can be switched by a simple configuration of movement in one direction, and in the pusher, the advance state where the roller is pushed out and the retreat state where the traveling unit can pass can be switched by a simple configuration of movement in one direction.

A traveling vehicle system according to an example embodiment of the present invention may further include a mover to move the traveling vehicle in one direction along the working track, a first driver to drive the stopper, a second driver to drive the pusher, and a controller configured or programmed to control the mover, the first driver, and the second driver. The controller may be configured or programmed to control the mover such that the traveling unit moves to a predetermined upstream-side position upstream of the predetermined position, control the first driver such that the stopper advances to a position where the roller is able to be pressed, and control the second driver such that the pusher pushes out the roller in the one direction. With this configuration, even in a case where the traveling vehicle cannot self-propel to the predetermined position, the traveling unit can be accurately moved to the predetermined position on the working track by the stopper and the pusher after the traveling unit is roughly moved to the predetermined upstream-side position by the mover. As a result, the positional accuracy can be maintained with simple control.

In a traveling vehicle system according to an example embodiment of the present invention, the controller may be configured or programmed to cause the stopper and then the pusher to advance to the moving region in this order when the traveling unit are positioned at the predetermined position, and cause the pusher and then the stopper to retreat from the moving region in this order when the traveling unit are moved from the predetermined position. In this configuration, since the stopper advances first, it is possible to prevent overtravel (overrun) the roller and, consequently, the traveling unit. Further, in this configuration, since the stopper retreats after the pressing force applied to the roller by the pusher decreases, the stopper is not caused to retreat in a state where an unintended force acts on the stopper.

In a traveling vehicle system according to an example embodiment of the present invention, the roller may be a side roller in contact with an inner side wall of the main body. In this configuration, when the traveling unit is moved, the parts included in the traveling unit can be effectively used.

A traveling vehicle system according to an example embodiment of the present invention may further include a plurality of sensors located above the predetermined position to measure a height position at various positions on upper surfaces of the traveling unit. The plurality of sensors may be located at positions corresponding to the traveling unit positioned at the predetermined position, and the plurality of sensors may simultaneously start measurement when the traveling unit is positioned at the predetermined position. In this configuration, the measurement by the plurality of sensors can be performed at the same time in one positioning.

According to example embodiments of the present invention, it is possible to improve positional accuracy when traveling units of traveling vehicles are stopped at the predetermined positions on the working tracks.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view illustrating a traveling vehicle system according to an example embodiment of the present invention.

FIG. 2 is a front schematic view of an overhead traveling vehicle of FIG. 1 as viewed from the front in a traveling direction.

FIG. 3 is a front view illustrating a traveling unit of a traveling vehicle traveling on a working track.

FIG. 4 is a cross-sectional view illustrating the working track and the traveling unit of the traveling vehicle in FIG. 3.

FIG. 5A is a cross-sectional view illustrating the working track and the traveling unit of the traveling vehicle. FIG. 5B is a plan view illustrating a mover of an example embodiment of the present invention.

FIG. 6 is a perspective view illustrating the working track.

FIG. 7 is a perspective view illustrating a positioning mechanism.

FIG. 8A is a plan view illustrating a stopper and a pusher having retreated to a retreat position. FIG. 8B is a plan view illustrating the stopper and the pusher having advanced to an advance position.

FIG. 9A is a plan view illustrating the stopper having advanced to the advance position and the pusher having started to advance to the advance position. FIG. 9B is a plan view illustrating the stopper and the pusher having advanced to the advance position.

FIG. 10A is a rear view illustrating a state of a side roller in contact with the stopper. FIG. 10B is a rear view illustrating a state of the side roller in contact with the pusher.

### DETAILED DESCRIPTION OF THE EXAMPLE EMBODIMENTS

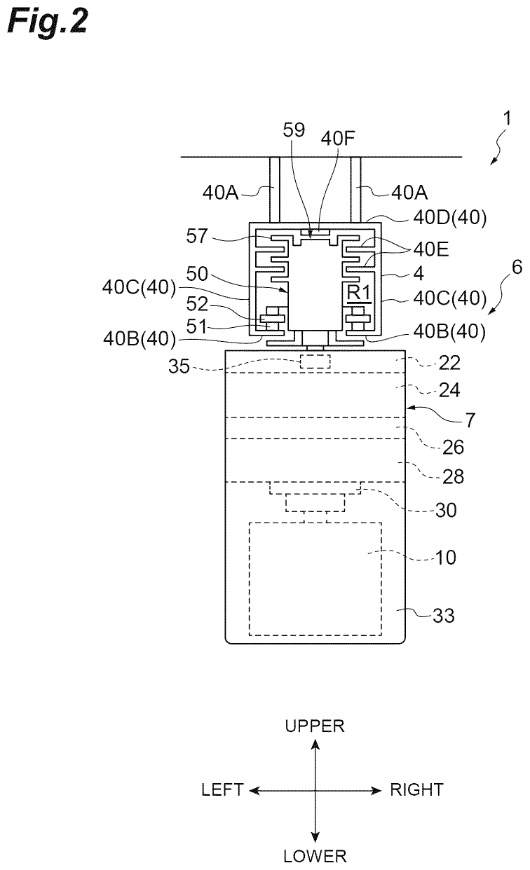

Hereinafter, example embodiments of the present invention will be described in detail with reference to the accompanying drawings. Note that, in description of the drawings, the same elements are denoted by the same reference signs, and redundant description will be omitted. In the present example embodiment, “upper”, “lower”, “left”, “right”, “front”, and “rear” directions are used for the sake of convenience in description. Note that, the “upper”, “lower”, “left”, “right”, “front”, and “rear” directions used in the present example embodiment are directions when a traveling vehicle 6 is viewed from a front side in a traveling direction of the traveling vehicle 6 as illustrated in FIG. 2.

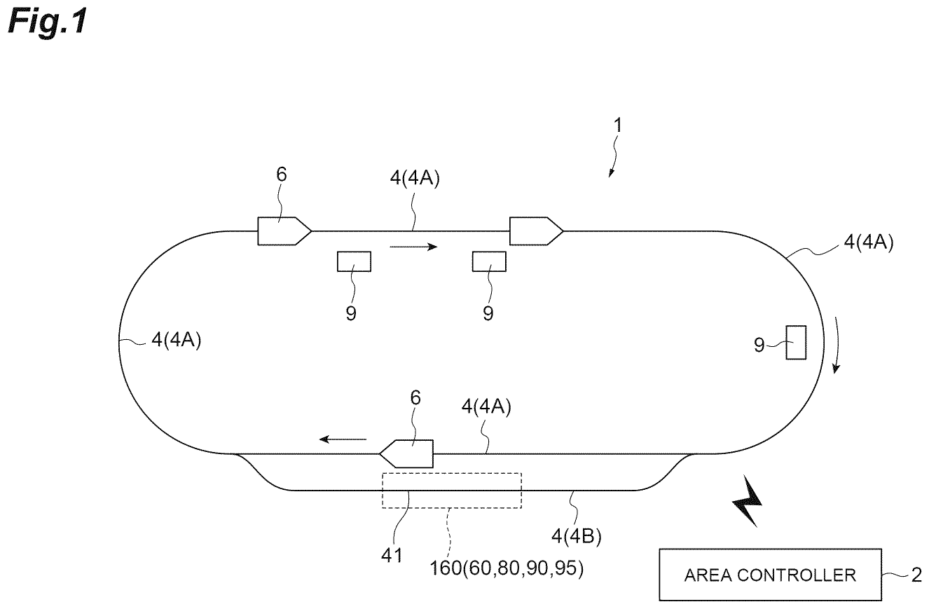

As illustrated in FIGS. 1 and 2, a traveling vehicle system 1 is a system to transport an article 10 between placement sections 9 and 9 by using an overhead traveling vehicle 6 movable along a traveling track (track) 4. Examples of the article 10 include a container such as a FOUP (Front Opening Unified Pod) to store a plurality of semiconductor wafers and a container to store a glass substrate, a container such as a reticle pod, and common parts. The traveling vehicle system 1 includes an area controller 2, a traveling track 4, a plurality of traveling vehicles 6, a plurality of placement sections 9, a working track 41, a mover 60, a positioning mechanism 80, an inspection device 90, and a maintenance controller 95.

The area controller 2 is an electronic control unit including a CPU (Central Processing Unit), a ROM (Read Only Memory), and a RAM (Random Access Memory). A cart controller 35 and the maintenance controller 95 in the traveling vehicle 6 are configured or programmed to communicate with the area controller 2. The area controller 2 can be configured, for example, as software that is a program stored in the ROM, loaded into the RAM, and executed by the CPU. The area controller 2 may be configured as hardware with electronic circuitry. The area controller 2 is configured or programmed to transmit a transportation command to the traveling vehicle 6 to transport the article 10.

The traveling track 4 is laid, for example, in the vicinity of a ceiling that is a space above the worker's head. The traveling track 4 is, for example, suspended from a ceiling. The traveling track 4 is a predetermined traveling path for the traveling vehicle 6 to travel. The traveling track 4 is supported by struts 40A and 40A. The traveling vehicle system 1 includes a main line 4A for travel in one direction around a predetermined area and a retreat section 4B in which a working track 41 provided with a working area 160 for maintenance of the traveling vehicle 6 is provided. Note that, in the retreat section 4B, the traveling vehicle 6 moves in a predetermined one direction.

The traveling track 4 includes a tubular rail body (main body) 40 including a pair of lower surface portions 40B and 40B, a pair of side surface portions 40C and 40C, and a top surface portion 40D, power feeders 40E, and a magnetic plate 40F. The rail body 40 accommodates (contains) a traveling unit 50 of the traveling vehicle 6. In other words, the rail body 40 has an internal space (moving region) R1 where the traveling unit 50 travels. The lower surface portions 40B extend in a traveling direction of the traveling vehicle 6 and define a lower surface of the rail body 40. The lower surface portions 40B are plate-shaped structures that cause the traveling rollers 51 of the traveling vehicle 6 to roll and travel. The side surface portions 40C extend in the traveling direction of the traveling vehicle 6 and define side surfaces of the rail body 40. The side surface portions 40C are plate-shaped structures to rotate side rollers 52 of the traveling vehicle 6. The top surface portion 40D extends in the traveling direction of the traveling vehicle 6 and defines an upper surface of the rail body 40.

Each power feeder 40E is configured to supply electric power to power feed cores 57 of the traveling vehicle 6 and to transmit and receive signals to and from the power feed cores 57. Each power feeder 40E is fixed to each of the pair of side surface portions 40C and 40C and extends along the traveling direction. The power feeders 40E supply electric power to the power feed cores ≡in a contactless state. The magnetic plate 40F generates

magnetic force for traveling or stopping with respect to the LDM (Linear DC Motor) 59 of the traveling vehicle 6. The magnetic plate 40F is fixed to the top surface portion 40D and extends along the traveling direction.

Traveling vehicle 6 travels along the traveling track 4 and transports the article 10. The traveling vehicle 6 is configured to be able to transfer the article 10. The traveling vehicle 6 is an automated overhead traveling vehicle. The number of traveling vehicles 6 included in the traveling vehicle system 1 is not particularly limited and is more than one. The traveling vehicle 6 includes a suspension unit (main body) 7, the traveling unit 50, and the cart controller 35. The suspension unit 7 includes a body frame 22, a traverse unit 24, a θ drive 26, an elevation driver 28, an elevation stage 30, and a cover 33.

The body frame 22 is connected to the traveling unit 50 and supports the traverse unit 24, the θ drive 26, the elevation driver 28, the elevation stage 30, and the covers 33. The traverse unit 24 allows the θ drive 26, the elevation driver 28, and the elevation stage 30 to collectively move in a right-angle direction with respect to an extending direction of the traveling track 4 (traveling direction of the traveling vehicle 6). The θ drive 26 rotates at least one of the elevation driver 28 and the elevation stage 30 within a predetermined angle range in a horizontal plane. The elevation driver 28 elevates and lowers the elevation stage 30 by reeling or unreeling a suspension such as a wire, a rope, and a belt. The elevation stage 30 is provided with a chuck and is able to grip or release the article 10. A pair of the covers 33 is provided, for example, on the front and the rear of the traveling vehicle 6 in the traveling direction. The covers 33 project and retreat not-illustrated claws or the like and prevent the article 10 from dropping during transportation.

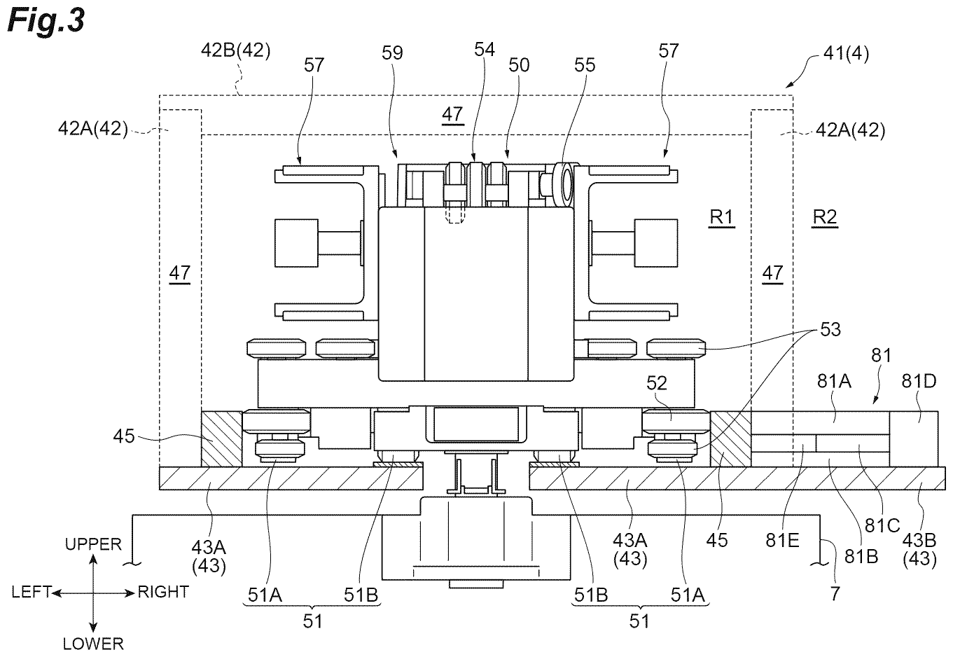

The traveling unit 50 causes the traveling vehicle 6 to travel along the traveling track 4. As illustrated in FIGS. 2 and 3, the traveling unit 50 includes the traveling rollers 51, the side rollers 52, branching rollers 53, auxiliary rollers 54, slanted rollers 55, the power feed cores 57, and the LDMs 59. Note that, in FIG. 2, the branching rollers 53, the auxiliary rollers 54, and the slanted roller 55 are not illustrated.

The traveling rollers 51 are roller pairs each including an outer wheel 51A as a traveling wheel and an inner wheel 51B as a traveling auxiliary wheel. The traveling rollers 51 are disposed on both of left and right ends at the front and the rear of the traveling unit 50. The traveling rollers 51 roll on the pair of lower surface portions 40B and 40B (or lower support portions 43 in FIG. 3 to be described later) of the traveling track 4. The side rollers 52 are able to come into contact with the side surface portion 40C (or side support portions 45 in FIG. 3 to be described later) of the traveling track 4. The branching rollers 53 are disposed to sandwich each of the side rollers 52 in the upper-lower direction. The side rollers 52 are able to come into contact with guides (not illustrated) disposed at a connection section, a branching section, or the like of the traveling track 4.

The auxiliary rollers 54 are roller groups each including a set of three rollers that is provided at each of the front and the rear of the traveling unit 50. The auxiliary rollers 54 are provided in order to prevent the LDMs 59, the power feed cores 57, and the like, from coming into contact with the magnetic plate 40F on an upper surface of the traveling track 4 when the traveling unit 50 is inclined to the front and the rear during traveling due to acceleration or deceleration. The slanted rollers 55 are provided at four corners of the LDM 59. The slanted rollers 55 are disposed in a state of being inclined from the front-rear direction. The slanted rollers 55 are provided to prevent an inclination due to centrifugal force when the traveling unit 50 travels in a curved section.

The power feed cores 57 are disposed at the front and the rear of the traveling unit 50 so as to sandwich each LDM 59 in a left-right direction. Power is fed in a contactless manner from each power feeder 40E disposed at the traveling track 4 and a variety of signals are transmitted and received in a contactless manner. The power feed cores 57 exchange signals with the cart controller 35. The LDMs 59 are provided at the front and the rear of the traveling unit 50. Each LDM 59 uses an electromagnet to produce magnetic force for traveling or stopping, between the LDM 59 and the magnetic plate 40F disposed on the upper surface of the traveling track 4.

As illustrated in FIG. 1, the placement sections 9 are disposed along the traveling track 4 and provided at positions where the article 10 can be delivered by the traveling vehicle 6. The placement sections 9 each include a buffer and a delivery port. The buffer is a placement section on which the article 10 is temporarily placed. The buffer is a placement section on which the article 10 is temporarily placed when the article 10 transported by the traveling vehicle 6 cannot be transferred to a target delivery port, for example, for the reason that another article 10 has been placed on the target delivery port. The delivery port is, for example, a placement section for delivering the article 10 to and from a semiconductor processing device (not illustrated) such as a cleaning device, a deposition device, a lithography device, an etching device, a thermal treatment device, and a planarization device. Note that, the processing device is not limited to a specific device and may be a variety of devices.

For example, the placement sections 9 are disposed to the side of the traveling track 4. In this case, the traveling vehicle 6 delivers the article 10 to and from each placement section 9 by causing the traverse unit 24 to laterally feed the elevation driver 28 or the like and by slightly elevating and lowering the elevation stage 30. Note that, although not illustrated, the placement sections 9 may be disposed immediately below the traveling track 4. In this case, the traveling vehicle 6 transfers the article 10 to and from each placement section 9 by elevating and lowering the elevation stage 30.

The cart controller 35 is an electronic control unit including a CPU, a ROM, a RAM, and the like. The cart controller 35 is configured or programmed to control various operations in the traveling vehicle 6. Specifically, the cart controller 35 is configured or programmed to control the traveling unit 50, the traverse unit 24, the θ drive 26, the elevation driver 28, and the elevation stage 30. The cart controller 35 can be configured, for example, as software that is a program stored in the ROM, loaded into the RAM, and executed by the CPU. The cart controller 35 may be configured as hardware with electronic circuitry. The cart controller 35 is configured or programmed to communicate with the area controller 2 by using the power feeders 40E (feeder lines) of the traveling track 4.

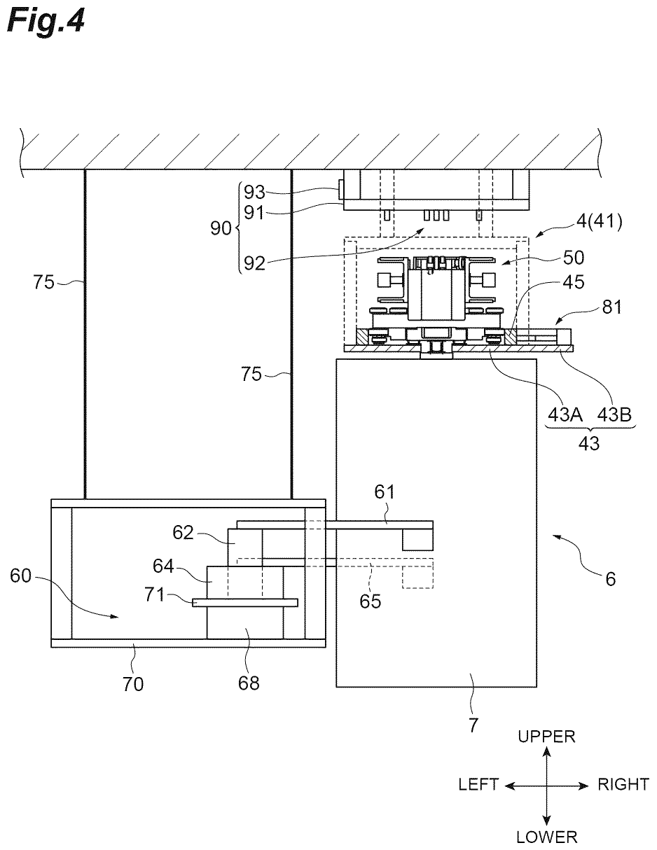

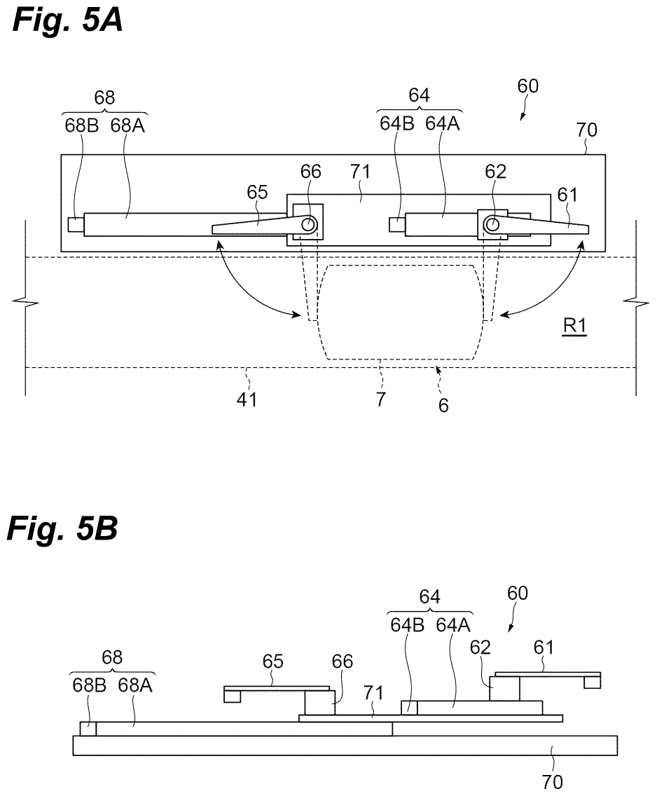

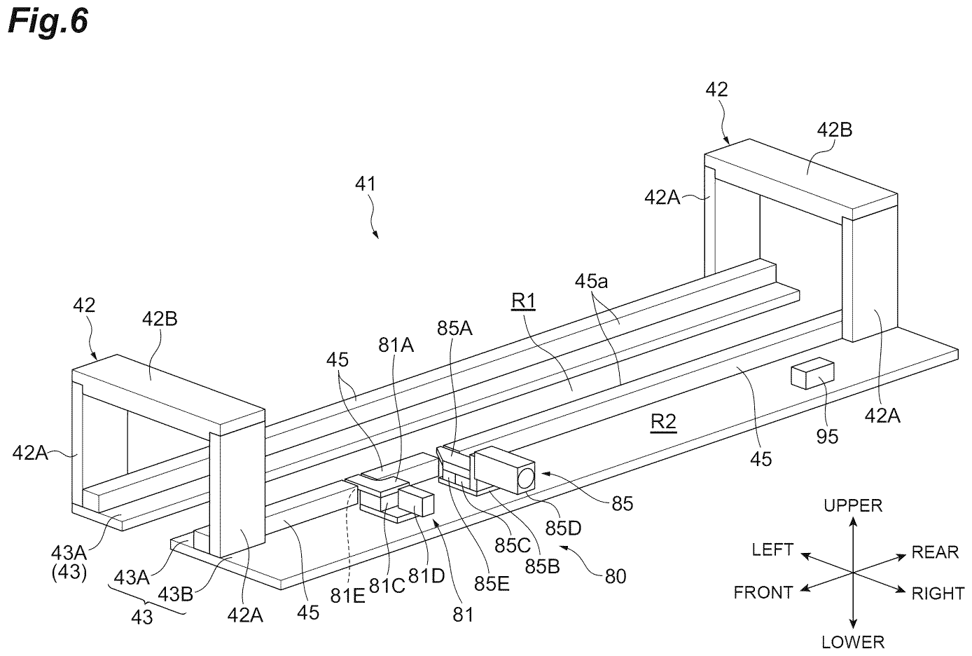

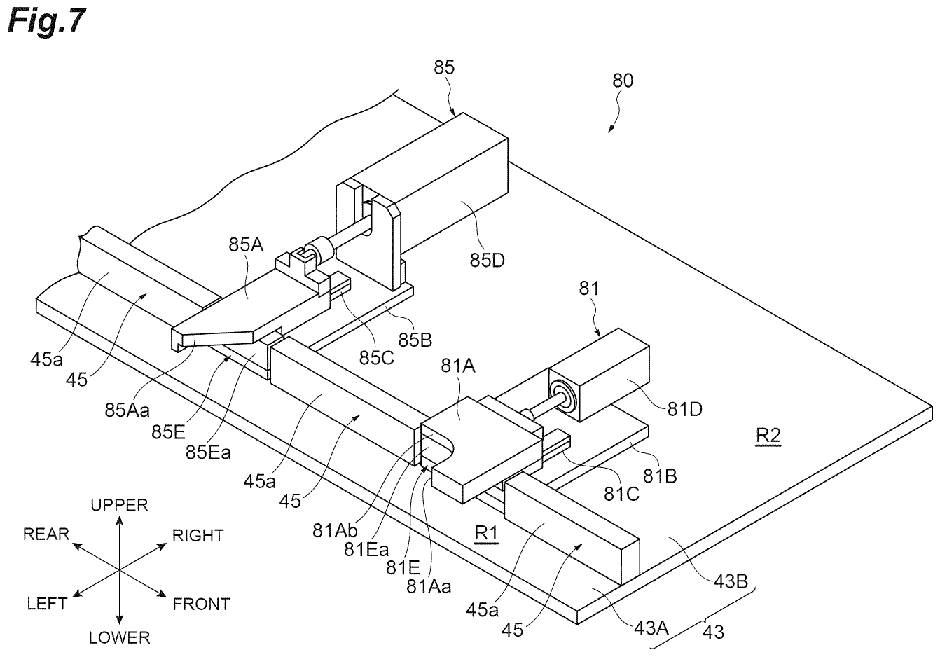

As illustrated in FIG. 1, the working area 160 is an area provided in a portion of the retreat section 4B and in which maintenance of each unit of the traveling unit 50 included in the traveling vehicle 6 is performed. The working track 41 (see FIGS. 3, 4, and 6), the mover 60 (see FIGS. 4, 5(A), and 5(B) ), the positioning mechanism 80 (see FIGS. 6 and 7), and the inspection device 90 (see FIG. 4) are provided in the working area 160.

The working track 41 extends in one direction such that both ends thereof are continuous (connected) to the traveling tracks 4 and 4, and defines an opening 47 that exposes at least a part (for example, the auxiliary roller 54, the slanted roller 55, the power feed core 57, the LDM 59, and the like) of the traveling unit 50 as illustrated in FIGS. 3 and 6. In other words, the working track 41 is not provided with the side surface portion 40C, the power feeder 40E, and the top surface portion 40D as provided in the traveling track 4, and portions corresponding to the side surface portion 40C, the power feeder 40E, and the top surface portion 40D of the traveling track 4 are the openings 47. Note that, since the power feeder 40E is not provided on the working track 41, the traveling vehicle 6 cannot self-propel.

The working track 41 includes frames 42 disposed at both ends of the working track 41, a pair of lower support portions 43 and 43, and a pair of side support portions 45 and 45.

The frame 42 includes a pair of side surface portions 42A and 42A and a top surface portion 42B. The pair of side surface portions 42A and 42A are plate-shaped structures disposed to face each other in the left-right direction and extending in a vertical direction. The side surface portion 42A is fixed to the ceiling via a bracket (not illustrated) and a strut (not illustrated). The top surface portion 42B is a plate-shaped structure that connects the pair of side surface portions 42A and 42A at upper ends of the pair of side surface portions 42A and 42A.

Each of the pair of lower support portions 43 and 43 supports the traveling unit 50 from below. More specifically, the lower support portion 43 supports the outer wheel 51A and the inner wheel 51B of the traveling roller 51 of the traveling unit 50 from below and rolls the outer wheel 51A and the inner wheel 51B. The lower support portions 43 are fixed to lower ends of the side surface portions 42A of the frames 42 and are connected to the pair of frames 42 and 42. In addition to inner portions 43A that roll the outer wheel 51A and the inner wheel 51B, outer portions 43B on which devices such as the positioning mechanism 80 and the maintenance controller 95 are placed are formed in the lower support portions 43 disposed on a right side. The outer portions 43B are located in the outer region R2 of the moving region R1 of the traveling unit 50 on the working track 41.

The side support portion 45 is a structure with which the side roller 52 of the traveling unit 50 comes into contact. The side support portion 45 is a square structure extending along a moving direction of the traveling unit 50. The side support portions 45 are fixed to the side surface portions 42A of the frames 42, are connected to the pair of frames 42 and 42, and are fixed to upper surfaces of the inner portions 43A of the lower support portions 43. In the side support portion 45 disposed on a right side, gaps for allowing a stopper 81 and a pusher 85 to be described in detail later to advance or retreat from an outside of the moving region R1 to an inside of the moving region R1 are provided at two places.

The mover 60 illustrated in FIGS. 4, 5A, and 5B is configured to move the traveling vehicle 6 on the working track 41 on which the traveling vehicle 6 cannot self-propel. The mover 60 moves the suspension unit 7 along the extending direction of the working track 41. More specifically, the traveling vehicle 6 is moved by moving the suspension unit 7 between a connection portion with the traveling track 4, which is one end of the working track 41 and a connection portion with the traveling track 4, which is the other end. The mover 60 includes a base plate 70, a moving plate 71, a pair of arms including a first arm 61 and a second arm 65, a first rotation driver 62, a second rotation driver 66, a first movement driver 64, and a second movement driver 68.

The base plate 70 is a plate-shaped structure that supports the moving plate 71, the first arm 61, the second arm 65, the first rotation driver 62, the second rotation driver 66, the first movement driver 64, and the second movement driver 68. The base plate 70 is suspended from the ceiling by a suspension 75. The base plate 70 is disposed below the working track 41 and on a side of the suspension unit 7 of the traveling vehicle 6 moving on the working track 41.

The moving plate 71 is a plate-shaped structure that supports the first arm 61, the second arm 65, the first rotation driver 62, the second rotation driver 66, the first movement driver 64, and the second movement driver 68. The moving plate 71 is movable along the moving direction of the suspension unit 7 with respect to the base plate 70. More specifically, the moving plate 71 is movable along the moving direction of the suspension unit 7 with respect to the base plate 70 by the second movement driver 68 including a linear motion (LM) guide 68A, a drive motor 68B, and the like.

The first arm 61 is disposed on an upstream side in the moving direction of the suspension unit 7 with respect to the second arm 65. That is, the first arm 61 comes into contact with a rear end (cover 33) of the suspension unit 7 when the suspension unit 7 is moved. Note that, the upstream side and a downstream side mentioned here refer to directions determined with reference to a preset moving direction of the suspension unit 7 in one direction. The first arm 61 moves by the first rotation driver 62 between a position (contact position) where the first arm 61 sandwiches the suspension unit 7 and a position (retreat position) where the first arm 61 retreats from the suspension unit 7. The first arm 61 and the first rotation driver 62 are provided to be movable in the moving direction of the suspension unit 7 with respect to the moving plate 71 by the first movement driver 64. More specifically, the first arm 61 and the first rotation driver 62 are provided to be movable in the moving direction of the suspension unit 7 with respect to the moving plate 71 by the first movement driver 64 including an LM guide 64A, a drive motor 64B, and the like.

The second arm 65 is disposed on a downstream side of the first arm 61 in the moving direction of the suspension unit 7. That is, the second arm 65 comes into contact with a front end of the suspension unit 7 when the suspension unit 7 is moved. The second arm 65 moves between a position where the second arm sandwiches the suspension unit 7 and a position where the second arm retreats from the suspension unit 7 by the second rotation driver 66. Unlike the first arm 61 and the first rotation driver 62, the second arm 65 and the second rotation driver 66 are provided so as not to be movable in the moving direction of the suspension unit 7 with respect to the moving plate 71.

As illustrated in FIGS. 6 and 7, on the working track 41 on which the traveling vehicle 6 cannot self-propel, the positioning mechanism 80 moves the traveling unit 50 of the traveling vehicle 6 to a predetermined position on the working track 41 to perform positioning. More specifically, the positioning mechanism 80 moves the traveling unit 50 such that an inspection target portion of the traveling unit 50 is positioned at an inspection position in the inspection device 90 disposed on the working track 41. The positioning mechanism 80 includes the stopper 81 and the pusher 85. The inspection target portion in the present example embodiment is, for example, the auxiliary roller 54, the slanted roller 55, the power feed core 57, the LDM 59, and the like.

The stopper 81 is a structure against which the side roller 52, which is one of rollers rotatably provided around an axis extending in the vertical direction in the traveling unit 50, is pressed. The stopper 81 is able to advance or retreat along a width direction (left-right direction) orthogonal to both a moving direction (front-rear direction) and a vertical direction (upper-lower direction) of the traveling unit 50 with respect to the moving region R1 of the traveling unit 50 on the working track 41. The stopper 81 is disposed on a downstream side with respect to the pusher 85 in the one direction (the moving direction of the traveling unit 50).

The pusher 85 moves the side roller 52 in the traveling unit 50 in one direction and presses the side roller 52 against the stopper 81 from one direction to position the traveling unit 50 at a predetermined position on the working track 41. The pusher 85 is able to advance or retreat along the width direction (left-right direction) with respect to the moving region R1 of the traveling unit 50 on the working track 41. The pusher 85 is disposed upstream of the predetermined position. The stopper 81 and the pusher 85 can press or push out the traveling unit 50 in a state of advancing to the moving region R1 of the traveling unit 50, and the traveling unit 50 can freely move in the moving region R1 in a state of retreating from the moving region R1 of the traveling unit 50.

The stopper 81 and the pusher 85 will be described in more detail. The stopper 81 includes a pressed structure 81A against which the side roller 52 is pressed, a first support 81B fixed to the lower support portion 43, a first linear guide 81C that slidably supports the pressed structure 81A along the width direction with respect to the first support 81B, a first driver 81D that advances or retreats the pressed structure 81A along the width direction, and a first side wall portion 81E that becomes a rolling surface of the side roller 52 when the pressed structure 81A is positioned at the retreat position.

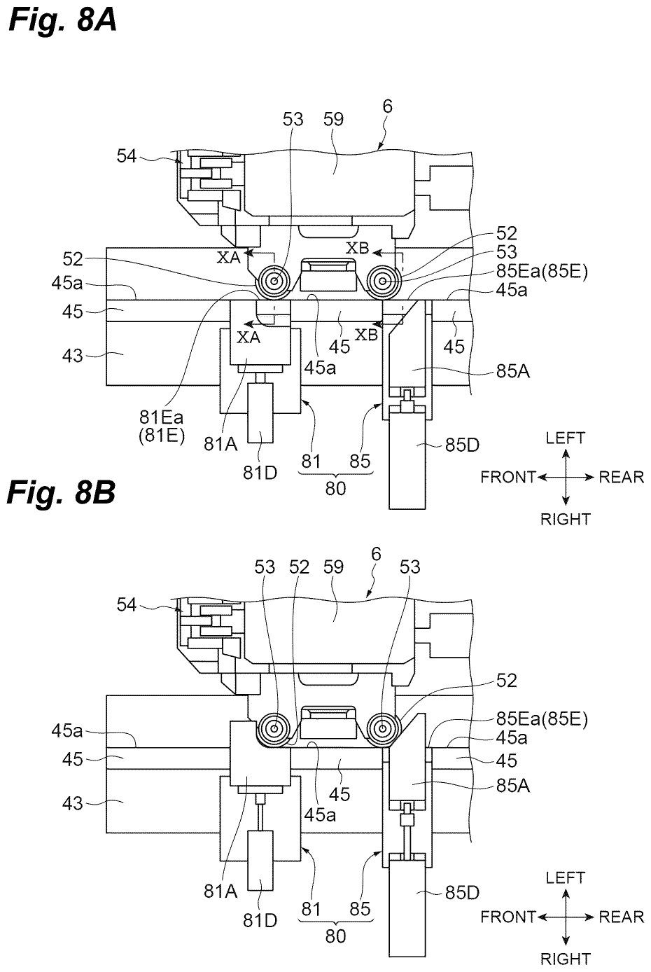

The pressed structure 81A is configured to advance or retreat between an advance position (see FIG. 8B) and a retreat position (see FIG. 8A) in the stopper 81. The pressed structure 81A is formed in an L shape in plan view viewed from above. The pressed structure 81A includes a pressed surface 81Aa on which a surface orthogonal to the moving direction of the traveling unit 50 is formed, and a guide surface 81Ab on which a surface parallel to the moving direction of the traveling unit 50 is formed. The pressed surface 81Aa is a surface with which the side roller 52 pushed out in one direction by the stopper 81 comes into contact when the pressed structure 81A is positioned at the advance position. The guide surface 81Ab is a surface that rolls and guides the side roller 52 when the pressed structure 81A is positioned at the advance position and the traveling unit 50 moves in one direction.

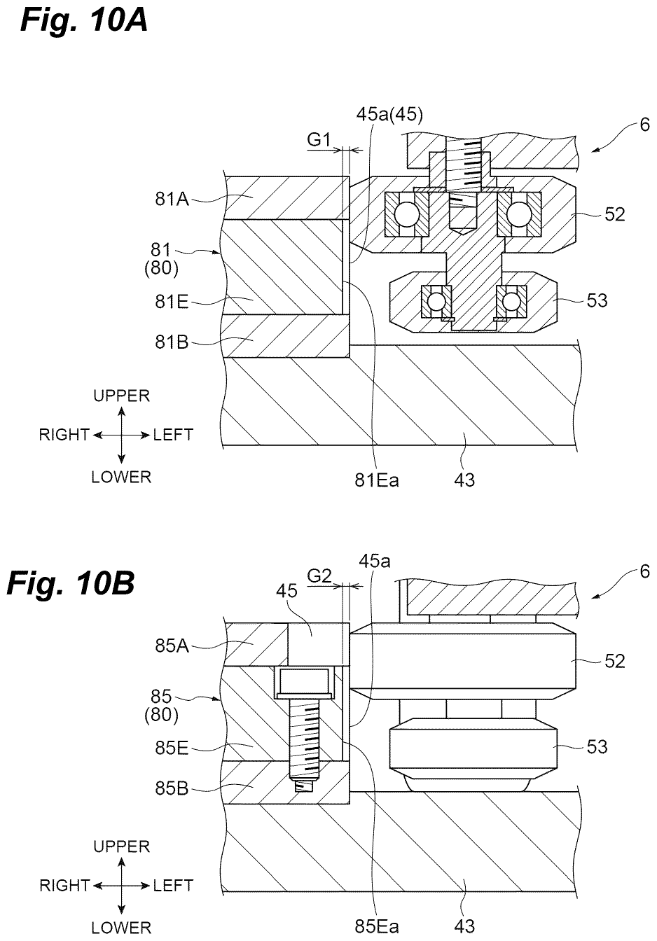

As illustrated in FIG. 10A, the pressed structure 81A advances to the advance position such that the guide surface 81Ab is flush with a guide surface 45a of the side support portion 45. In other words, the guide surface 81Ab of the pressed structure 81A and the guide surface 45a of the side support portion 45 have the same distance from a center position in the width direction of the working track 41. On the other hand, a rolling surface 81Ea of the first side wall portion 81E is located at a position (that is, a position distant from the center position in the width direction of the working track 41) ahead of the guide surface 81Ab of the pressed structure 81A. Note that, a distance G1 between the guide surface 81Ab and the rolling surface 81Ea is, for example, about 1 mm.

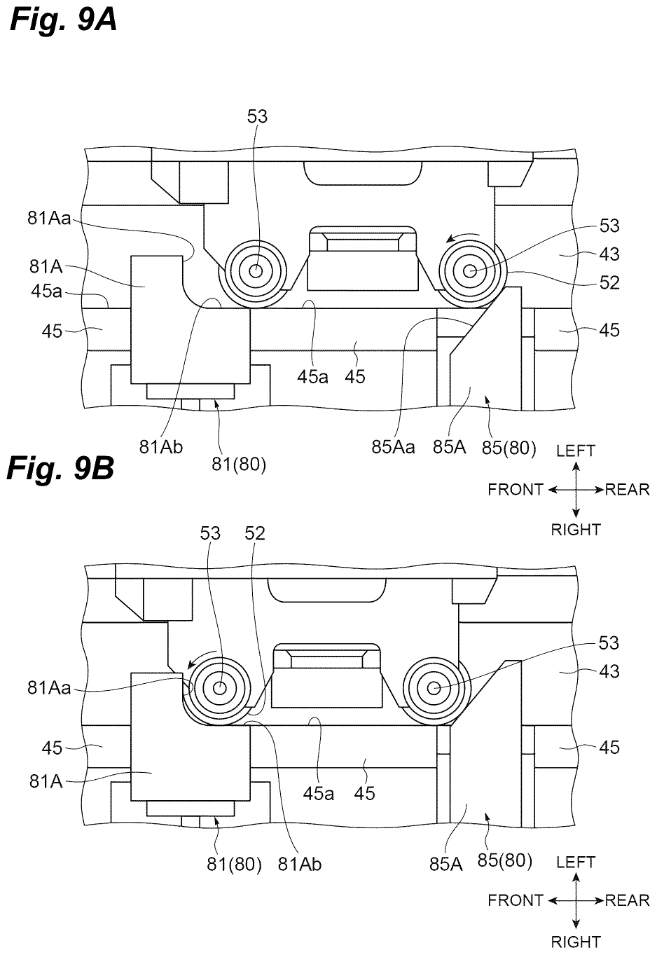

When the stopper 81 moves toward the retreat position in a state where the side roller 52 is pressed, the side roller 52 in contact with the pressed surface 81Aa of the stopper 81 rotates to a left side (counterclockwise) (arrow direction illustrated in FIG. 9B) as illustrated in FIG. 9B. At this time, the guide surface 81Ab of the stopper 81 is separated from the side roller 52 in a retreating direction. At this time, when the rolling surface 81Ea of the first side wall portion 81E is in a flush positional relationship with the guide surface 81Ab of the stopper 81 at the advance position, the side roller 52 remains a state of coming into contact with the rolling surface 81Ea. Accordingly, the side roller 52 slides on the rolling surface 81Ea, which causes wear. However, in the configuration having the distance G1, since the side roller 52 does not come into contact with the rolling surface 81Ea, the wear of the side roller 52 when the stopper 81 is moved to the retreat position can be reduced.

As illustrated in FIGS. 6 and 7, the pusher 85 includes a pressing structure 85A that is pushed in one direction by the side roller 52, a second support 85B fixed to the lower support portion 43 with a bolt or the like, a second linear guide 85C that slidably supports the pressing structure 85A along the width direction with respect to the second support 85B, a second driver 85D that advances or retreats the pressing structure 85A along the width direction, and a second side wall portion 85E that becomes the rolling surface of the side roller 52.

The pressing structure 85A is configured to advance or retreat between the advance position and the retreat position in the pusher 85. The pressing structure 85A has a pressing surface 85Aa that is a surface inclined with respect to a surface orthogonal to the moving direction of the traveling unit 50. The pressing surface 85Aa is located at a downstream-side end of the pressing structure 85A in the moving direction of the traveling unit 50, and in a plan view as seen from above, a portion between a proximal end side and a distal end side is inclined to the downstream side. The pressing surface 85Aa is capable of advancing in an advancing direction to push out the side roller 52 to the downstream side in the moving direction of the traveling unit 50 while rotating the side roller 52.

As illustrated in FIG. 10B, the second side wall portion 85E is disposed such that the rolling surface 85Ea of the second side wall portion 85E is at a position ahead of the guide surface 45a of the side support portion 45. In other words, the rolling surface 85Ea of the second side wall portion 85E is disposed so as to be farther from the center position of the working track 41 in the width direction than the guide surface 45a of the side support portion 45. Note that, a distance G2 between the guide surface 45a and the rolling surface 85Ea is, for example, about 1 mm.

In a case where the traveling unit 50 is positioned at a predetermined upstream-side position, when the pusher 85 moves toward the advance position, the side roller 52 in contact with the pressing surface 85Aa of the pusher 85 rotates to a left side (counterclockwise) (arrow direction illustrated in FIG. 9A) as illustrated in FIG. 9A. At this time, when the rolling surface 85Ea of the second side wall portion 85E is in a flush positional relationship with the guide surface 45a of the side support portion 45, the side roller 52 remains a state of coming into contact with the rolling surface 85Ea. In this case, the side roller 52 slides on the rolling surface 85Ea, which causes wear. In the 1 configuration having the distance G2, since the side roller 52 does not come into contact with the rolling surface 85Ea, the wear of the side roller 52 when the pusher 85 is moved to the advance position can be reduced.

As illustrated in FIG. 4, the inspection device 90 is disposed above a position where the traveling unit 50 is positioned on the working track 41 by the stopper 81 and the pusher 85. The inspection device 90 includes a moving body 91 configured to be movable in the vertical direction, and a plurality of contact sensors (sensors) 92 that is provided in the moving body 91 and detects presence or absence of contact with each unit of the traveling 50. The moving body 91 supported to be vertically movable directly or indirectly on the working track 41, the ceiling, or the like. The moving body 91 is vertically driven by a driver 93 such as a motor. Note that, the inspection device 90 of the present example embodiment does not include a mechanism for moving the moving body in a horizontal direction.

A movement amount (lowering amount) of the moving body 91 in the vertical direction and a detection result in the contact sensor 92 are acquired by the maintenance controller 95. The lowering amount of the moving body 91 can be acquired, for example, based on a driving amount of the driver 93, or can be acquired by a sensor or the like that measures a position of the moving body 91. The inspection device 90 having such a configuration can detect a height position of each unit (a portion to be contacted by the contact sensor 92) in the traveling unit 50. In the inspection device 90 of the present example embodiment, since a stop position of the traveling unit 50 can be precisely determined, the plurality of contact sensors 92 can simultaneously perform measurement. In other words, in the inspection device 90 of the present example embodiment, the height positions of a plurality of places can be measured by lowering the moving body 91 once.

The maintenance controller 95 illustrated in FIG. 6 mainly controls the mover 60, the positioning mechanism 80, and the inspection device 90. The maintenance controller 95 is disposed, for example, on the outer portion 43B of the lower support portion 43 on the working track 41. The maintenance controller 95 is an electronic control unit including a CPU (Central Processing Unit), a ROM (Read Only Memory), and a RAM (Random Access Memory). The maintenance controller 95 is also configured or programmed to communicate with the cart controller 35 and the area controller 2 in the traveling vehicle 6. The maintenance controller 95 can be configured, for example, as software that is a program stored in the ROM, loaded into the RAM, and executed by the CPU. The maintenance controller 95 may be configured as hardware with electronic circuitry.

The maintenance controller 95 of the present example embodiment is configured or programmed to control the mover 60 such that the traveling unit 50 moves to upstream of the predetermined position controls the driver (first driver 81D) of the stopper 81 such that the stopper (pressed structure 81A) advances to a position where the side roller 52 can be pressed, and controls the driver (second driver 85D) of the pusher 85 such that the pusher 85 pushes out the side roller 52 in one direction. In addition, the maintenance controller 95 of the present example embodiment is configured or programmed to cause the stopper 81 and the pusher 85 to advance to the moving region R1 in this order when the traveling unit 50 is positioned at a predetermined position, and cause the pusher 85 and the stopper 81 to retreat from the moving region R1 in this order when the traveling unit 50 is moved from the predetermined position. The maintenance controller 95 of the present example embodiment is configured or programmed to control the inspection device 90 to start measurement after the traveling unit 50 is stopped at a predetermined position by the stopper 81 and the pusher 85.

In the traveling vehicle system 1 having such a configuration, an operation when the traveling unit 50 is positioned at a predetermined position on the working track 41 will be described. As illustrated in FIGS. 5A and 5B, the mover 60 advances the second arm 65 to the moving region of the traveling vehicle 6 (suspension unit 7), and waits until the suspension unit 7 travels to a position in contact with the second arm 65. When the suspension unit 7 temporarily stops at the position in contact with the second arm 65, the first rotation driver 62 rotates the first arm 61, and the first movement driver 64 moves the first arm 61 and the first rotation driver 62 forward (to the downstream side in the moving direction of the traveling vehicle 6). As a result, the mover 60 sandwiches the suspension unit 7 of the traveling vehicle 6 between the first arm 61 and the second arm 65.

Next, the mover 60 moves the moving plate 71 (that is, the mover 60 moves the first arm 61, the first rotation driver 62, the second arm 65, and the second rotation driver 66 forward while maintaining a distance between the first arm 61 and the second arm 65). As a result, the mover 60 moves the suspension unit 7 forward in a state of being sandwiched between the first arm 61 and the second arm 65, and moves the suspension unit 7 to a predetermined upstream-side position which is upstream side of the predetermined position in the working track 41. Note that, the predetermined upstream-side position is a position on the upstream side within a range of a distance in which the pusher 85 can push the side roller 52 with the predetermined position as a reference position, and is, for example, a position within a range of 4 m on the upstream side of the predetermined position. The mover 60 releases the sandwiching of the suspension unit 7 by the first arm 61 and the second arm 65 at the predetermined upstream-side position.

When the traveling unit 50 of the traveling vehicle 6 moves to the predetermined upstream-side position, both the stopper 81 and the pusher 85 are positioned at the retreat positions as illustrated in FIG. 8A. In such a state, first, the stopper 81 advances to the moving region R1 of the traveling unit 50. Next, as illustrated in FIG. 9A, the pusher 85 advances to the moving region R1 of the traveling unit 50. The side roller 52 rotates to a left side (counterclockwise) (arrow direction illustrated in FIG. 9A) as the pusher 85 advances, and are simultaneously pushed forward. Then, as illustrated in FIG. 9B, when the pusher 85 completes the advancement to the advance position, the side roller 52 is in a state of being pressed against the pressed surface 81Aa of the stopper 81, and an operation of positioning the traveling unit 50 at a predetermined position of the working track 41 is completed.

Next, after the traveling unit 50 is positioned at the predetermined position on the working track 41, the inspection device 90 lowers the moving body 91 and brings the contact sensor 92 into contact with each unit of the traveling unit 50. As a result, the inspection device 90 acquires the height position of each part of the traveling unit 50.

When the inspection by the inspection device 90 is completed, first, the pusher 85 retreats from the moving region R1 of the traveling unit 50, and subsequently, the stopper 81 retreats from the moving region R1 of the traveling unit 50. As a result, the restraint of the traveling unit 50 by the positioning mechanism 80 is released. Next, the mover 60 sandwiches the suspension unit 7 between the first arm 61 and the second arm 65 at a predetermined position by the above-described procedure. Thereafter, the mover 60 moves the suspension unit 7 forward in a state of being sandwiched between the first arm 61 and the second arm 65, and moves the suspension unit 7 to a downstream end of the working track 41. The traveling vehicle 6 having reached the downstream end of the working track 41 (upstream-side end of the traveling track 4) can receive electric power by the power feeder 40E, and can self-propel. The traveling vehicle 6 receives a transport command from the area controller 2 and moves to a destination included in the transport command.

The operation effects of the traveling vehicle system 1 of the above example embodiment will be described. In the traveling vehicle systems 1 of the above example embodiments, the stopper 81 and the pusher 85 to position the traveling unit 50 at the predetermined position on the working track 41 are provided. Specifically, the pusher 85 presses the side roller 52 provided in the traveling unit 50 in one direction against the stopper 81 provided so as to advance or retreat with respect to the moving region R1 of the traveling unit 50, and thus, the traveling unit 50 is positioned at the predetermined position. As a result, it is possible to improve positional accuracy when the traveling unit 50 of the traveling vehicle 6 is stopped at the predetermined position of the working track 41, as compared with, for example, stopping the traveling unit 50 at the predetermined position on the working track 41 by controlling the driver of the traveling unit 50 or controlling the mover 60 that moves the traveling vehicle 6.

In the traveling vehicle systems 1 of the above example embodiments, a target with which the stopper and the pusher come into contact is a roller. The roller is subject to wear. Accordingly, durability is excellent as compared with a case where the stopper and the pusher come into contact with other portions of the traveling unit 50. In addition, such a roller is easy to replace even in a case where wear or distortion occurs as compared with other portions, and is also excellent in terms of management.

In the traveling vehicle systems 1 of the above example embodiments, both the stopper 81 and the pusher 85 are able to advance or retreat along the width direction with respect to the moving region R1 of the traveling unit 50 on the working track 41. As a result, in the stopper 81, an advance state where the side roller 52 is pressed and a retreat state where the traveling unit 50 can pass can be switched with a simple configuration. In addition, the pusher 85 can also switch between an advance state where the side roller 52 pushes out and a retreat state where the traveling unit 50 can pass with a simple configuration.

In the traveling vehicle systems 1 of the above example embodiments, the mover 60 moves the traveling unit 50 to the predetermined upstream-side position upstream of the predetermined position, the stopper 81 advances to the advance position where the side roller 52 can be pressed, and the pusher 85 advances to the advance position so as to push out the side roller 52 in one direction. As a result, after the traveling unit 50 is roughly moved to the predetermined upstream-side position, the traveling unit 50 can be accurately moved to the predetermined position of the working track 41 by the stopper 81 and the pusher 85.

In the traveling vehicle systems 1 of the above example embodiments, when the traveling unit 50 is positioned at the predetermined position, the stopper 81 and the pusher 85 advance to the moving region R1 in this order, and when the traveling unit 50 is moved from the predetermined position, the pusher 85 and the stopper 81 retreat from the moving region R1 in this order. As a result, when the traveling unit 50 is positioned at the predetermined position, since the stopper 81 advances first, it is possible to prevent the side roller 52 and the traveling unit 50 from going too far. Further, when the traveling unit 50 is moved from the predetermined position, since the stopper 81 retreats after pressing force to the side roller 52 by the pusher 85 decreases, the stopper 81 is not retreated in a state where abnormal force acts. As a result, the side roller 52 does not slide on the stopper 81, and the wear of the side roller 52 can be reduced.

In the traveling vehicle systems 1 of the above example embodiments, since the rollers pressed against the stopper 81 and pushed out by the pusher 85 are the side rollers 52, parts provided in the traveling unit 50 can be effectively used when the traveling unit 50 is moved. Further, in the configuration in which the stopper 81 and the pusher 85 advance along the width direction, it is necessary to advance the stopper 81 and the pusher 85 to the position of the side roller 52. However, in the above example embodiment, since the side roller 52 is disposed on the outer side in the width direction, the stroke of each of the drivers 81D and 85D of the stopper 81 and the pusher 85 can be reduced.

In the traveling vehicle systems 1 of the above example embodiments, the plurality of contact sensors 92 to measure height positions at various positions on the upper surfaces of the traveling unit 50 are disposed at a position corresponding to the traveling unit 50 positioned at the predetermined position, and measurement is started simultaneously when the traveling unit 50 is positioned at the predetermined position. Thus, measurement by the plurality of contact sensors 92 can be performed at the same time in one positioning.

Although example embodiments have been described above, the present invention is not limited to the above example embodiments. Various modifications can be made without departing from the gist of the present invention.

In the traveling vehicle systems 1 of the above example embodiments, an example in which the pusher 85 provided in the lower support portion 43 pushes out the side roller 52 in one direction to press the side roller 52 against the stopper 81 has been described, but the present invention is not limited thereto. For example, the pusher 85 may use, as a pusher, the first arm 61 of the mover 60, or may use, as a pusher, a pair of arms including the first arm 61 and the second arm 65. In this case, the suspension unit 7 is moved forward by the first arm 61 or the pair of arms including the first arm 61 and the second arm 65, and thus, the side roller 52 in the traveling unit 50 is pressed against the stopper 81. Even in this case, positioning is performed with reference to the traveling unit 50 itself (side roller 52). As a result, it is possible to improve positional accuracy when the traveling unit 50 of the traveling vehicle 6 is stopped at the predetermined position on the working track 41.

In the traveling vehicle systems 1 of the above example embodiments and the above modifications, an example in which the stopper 81 and the pusher 85 are able to advance or retreat along the width direction orthogonal to both the moving direction and the vertical direction of the traveling vehicle 6 has been described, but the present invention is not limited thereto. For example, an opening may be provided in the lower support portion 43, and the pusher 85 and the stopper 81 may advance to the moving region RI from below. Further, in the moving direction of the traveling unit 50, the stopper 81 may advance from the front side, and the pusher 85 may advance from the rear side. Thus, the stopper 81 and the pusher 85 can be freely combined in the advancing direction.

In the traveling vehicle systems 1 of the above example embodiments and the above modifications, the side roller 52 has been described as an example of the roller rotatably provided around the axis extending in the vertical direction. However, for example, the branching roller 53 provided in the traveling unit 50 or a new roller provided so as to be positioned on a side surface of the traveling unit 50 may be used. Even in this case, the stopper 81 and the pusher 85 having the above configuration can be used.

In the traveling vehicle systems 1 of the above example embodiments and the above modifications, an example in which the pair of arms including the first arm 61 and the second arm 65 is provided as the mover 60 and the pair of arms sandwiches the suspension unit 7 to move the traveling vehicle 6 has been described, but the present invention is not limited thereto. For example, the mover may include a block that sandwiches the branching roller 53 provided in the traveling unit 50 and a driver that moves the block along the extending direction of the working track 41. Even in this case, the traveling unit 50 can be moved to the predetermined upstream-side position, and the side roller 52 in the traveling unit 50 can be moved to the position to be pressed against the stopper 81.

In the traveling vehicle systems 1 of the above example embodiments and the above modifications, the reason why the traveling vehicle 6 cannot self-propel is that the power feeder 40E is not provided in the working track 41, but the present invention is not limited thereto. For example, in a case where the traveling vehicle 6 is driven by a linear motor, the reason may be that the magnetic plate 40F is not provided on the working track 41 and the traveling vehicle cannot self-propel.

In the traveling vehicle systems 1 of the above example embodiments and the above modifications, an example in which the working track 41 is configured such that the traveling vehicle 6 cannot self-propel has been described. However, the above-described positioning mechanism 80 may be disposed on the working track 41 configured such that the traveling unit 50 can self-propel. There is a limit to the positional accuracy of controlling the driver of the traveling unit 50 to stop the traveling unit 50 at the predetermined position. However, when the positioning mechanism 80 described in the above example embodiments and the above modifications is disposed, the traveling unit 50 can be positioned at the desired position on the working track 41 after the traveling unit 50 is stopped. As a result, the traveling unit 50 can be accurately positioned with respect to the inspection device disposed on the working track 41.

While example embodiments of the present invention have been described above, it is to be understood that variations and modifications will be apparent to those skilled in the art without departing from the scope and spirit of the present invention. The scope of the present invention, therefore, is to be determined solely by the following claims.

1-6. (canceled)

7. A traveling vehicle system in which a traveling vehicle travels on a traveling track on which a traveling unit of the traveling vehicle travels and including a main body extending along a traveling path of the traveling vehicle, the traveling vehicle system comprising:
a working track connected to the traveling track and including an opening to expose at least a portion of the traveling unit to an external space;
a stopper movable to advance or retreat with respect to a moving region of the traveling unit on the working track, the stopper being included in the traveling unit and against which a roller rotatable around an axis extending in a vertical direction is to be pressed; and
a pusher to move the traveling unit in the one direction and press the roller against the stopper from the one direction to position the traveling unit at a predetermined position on the working track.

8. The traveling vehicle system according to claim 7, wherein the stopper and the pusher are movable to advance or retreat along a width direction orthogonal to both a moving direction and a vertical direction of the traveling unit with respect to the moving region of the traveling unit on the working track.

9. The traveling vehicle system according to claim 7, further comprising:
a mover to move the traveling vehicle in one direction along the working track;
a first driver to drive the stopper;
a second driver to drive the pusher; and
a controller configured or programmed to control the mover, the first driver, and the second driver; wherein
the controller is configured or programmed to control the mover such that the traveling unit moves to a predetermined upstream-side position upstream of the predetermined position, control the first driver such that the stopper advances to a position where the roller is able to be pressed, and control the second driver such that the pusher pushes out the roller in the one direction.

10. The traveling vehicle system according to claim 9, wherein the controller is configured or programmed to cause the stopper and then the pusher to advance to the moving region in this order when the traveling unit is positioned at the predetermined position, and cause the pusher and then the stopper to retreat from the moving region in this order when the traveling unit is moved from the predetermined position.

11. The traveling vehicle system according to claim 7, wherein the roller is a side roller in contact with an inner side wall of the main body.

12. The traveling vehicle system according to claim 7, further comprising:
a plurality of sensors located above the predetermined position to measure a height position at various positions on upper surfaces of the traveling unit; wherein
the plurality of sensors are located at positions corresponding to the traveling unit at the predetermined position; and
the plurality of sensors are configured to start measurement simultaneously when the traveling unit is the predetermined position.
